(19) United States
(12) Patent Application Publication
(10) Pub. No.: US 2006/0068332 A1
(43) Pub. Date: Mar. 30, 2006

(54) Method for fabricating carrier structure integrated with semiconductor element

(75) Inventor: Chi-Ming Chen, Hsin-chu (TW)

Correspondence Address: Mr. William F. Nixon;SQUIRE SANDERS & DEMPSEY LLP, 14th Floor, 8000 Towers Crescent Drive, Tysons Corner, VA, 22182-2700, US

(73) Assignee: Phoenix Precision Technology Corporation

(21) Appl. No.: 11/022,753

(22) Filed: Dec. 28, 2004

(30) Foreign Application Priority Data
Sep. 29, 2004 (TW) 093129361

(51) Int. Cl. G03F 7/00

(52) U.S. Cl. 430/312; 430/315

(57) ABSTRACT

A method for fabricating a carrier structure integrated with a semiconductor element is proposed. First, a carrier having at least one opening therein is provided, and at least one semiconductor element is embedded in the opening. Then, a photosensitive insulating layer is formed on the carrier and filled into a gap between the opening of the carrier and the semiconductor element, such that the semiconductor element is fixed in the opening. Subsequently, the photosensitive insulating layer is patterned, and build-up circuits are formed on the semiconductor element. By such arrangement, the overall fabrication processes are simplified and the fabrication cost can be reduced.

### FIELD OF THE INVENTION

The present invention relates to methods for fabricating carrier structures integrated with semiconductor elements, and more particularly, to a method for embedding and fixing a semiconductor element in.

### BACKGROUND OF THE INVENTION

Along with the evolution of semiconductor packaging technology, different types of packages for semiconductor elements have been developed. Such semiconductor package normally comprises a semiconductor chip mounted on and electrically connected to a substrate or lead frame, and an encapsulant made of a resin material for encapsulating the chip.

The method for electrically connecting the semiconductor chip to the substrate or lead frame currently includes a wire-bonding technique or a flip-chip bonding technique. For either of a wire-bonded package or a flip-chip package, the semiconductor chip is formed with a plurality of bond pads thereon where the electrical connection is established. For example of the flip-chip bonding technique, first, a passivation layer is applied over a surface of the chip, with electrode pads on the semiconductor chip being exposed from the passivation layer. An under bump metallurgy (UBM) layer comprising a plurality of metal layers is formed on the exposed electrode pads by sputtering and electroplating processes. Then, a photosensitive insulating layer is disposed over the passivation layer and has a plurality of openings for exposing the UBM layer. A solder material such as a Sn/Pb alloy is coated on the UBM layer through the openings of the photosensitive insulating layer by a screen-printing technique. A reflow-soldering process is performed to bond the solder material to the UBM layer. Then, the photosensitive insulating layer is removed. Subsequently, the reflow-soldering process is repeated to form the solder material as metal bumps on the chip, such that the chip can be electrically connected to the packaging substrate via the metal bumps.

The semiconductor chip is mounted on the packaging substrate or lead frame prior to being electrically connected to the same. In a conventional semiconductor package, the chip is directly attached to an upper surface of the packaging substrate and encapsulated by the encapsulant, and solder balls are implanted on a lower surface of the substrate. Such stacking arrangement increases the overall height of the package and does not facilitate size miniaturization thereof.

Moreover, for either of the flip-chip package or wire-bonded package, fabrication of the packaging substrate and encapsulation of the semiconductor chip employ different fabrication apparatuses and processes, which involve complex fabrication processes and require high fabrication cost. Further, during the encapsulating process, the packaging substrate mounted with the chip is placed in a mold, and an epoxy resin material is injected into a cavity of the mold to form the encapsulant for encapsulating the chip. However, since practically the mold is restricted by the design of the semiconductor package, and the size of mold cavity and clamping positions of the mold may not be precisely made, the substrate cannot be strongly clamped by the mold, and the injected resin material would easily flash to unintended areas on the substrate. This not only degrades the surface planarity and appearance of the semiconductor package, but also may contaminate predetermined positions on the substrate for subsequently mounting solder balls. As a result, the quality of electrical connection of the semiconductor package is adversely affected, and the yield and reliability of the semiconductor package are also deteriorated.

In addition, for general fabrication processes of semiconductor packages, first, a carrier manufacturer produces suitable chip carriers such as packaging substrates or lead frames. Then, these chip carriers are transferred to a package manufacturer where chip-mounting, molding and ball-implanting processes are performed to form semiconductor packages having electronic functions required by clients. Therefore, different manufacturers (including carrier manufacturer and package manufacturer) are involved in the fabrication of semiconductor packages, and the practical fabrication processes are complicated and difficult in interface integration. Moreover, if the functional design of packages is to be altered, the associated changes and interface integration would become more complex and difficult, thereby not providing sufficient flexibility in design alternation and economical benefits.

Therefore, the problem to be solved here is to provide a carrier structure integrated with a semiconductor chip that is embedded in an opening of the carrier, so as to eliminate the above drawbacks in the prior art.

### SUMMARY OF THE INVENTION

In light of the above prior-art drawbacks, a primary objective of the present invention is to provide a method for fabricating a carrier integrated with a semiconductor element, wherein after the semiconductor element is embedded in an opening of the carrier, a photosensitive insulating layer for use in a subsequent patterning process for fabrication of build-up circuits is filled into the opening to fix the semiconductor element in place, such that the fabrication processes are simplified.

Another objective of the present invention is to provide a method for fabricating a carrier integrated with a semiconductor element, wherein a photosensitive insulating layer serves as a material for fixing the semiconductor element in place and for use in a subsequent patterning process for fabrication of build-up circuits, thereby reducing the material and fabrication cost.

A further objective of the present invention is to provide a method for fabricating a carrier integrated with a semiconductor element, wherein the semiconductor element is fixed in an opening of the carrier, and build-up circuits are formed on the semiconductor element, making these two procedures be combined in the same set of fabrication processes of the carrier.

In accordance with the foregoing and other objectives, the present invention proposes a method for fabricating a carrier integrated with a semiconductor element. In a preferred embodiment of the present invention, the method comprises the steps of: providing a carrier having at least one opening therein; embedding at least one semiconductor element in the opening of the carrier; and forming a photosensitive insulating layer over the carrier and filling the photosensitive insulating layer into a gap between the opening of the carrier and the semiconductor element, such that the semiconductor element is fixed in the opening.

Besides fixing the semiconductor element in place, the photosensitive insulating layer is further used in a subsequent patterning process for fabrication of build-up circuits. When the photosensitive insulating layer is applied over the carrier by coating or pressing, before being cured, the photosensitive insulating layer having fluidity is filled into the gap between the opening of the carrier and the semiconductor element, such that the semiconductor element can be strongly fixed in the opening after the photosensitive insulating layer is cured. Thus, the photosensitive insulating layer serves as a binding material without the need of an additional binding material, thereby saving the cost on the binding material. The photosensitive insulating layer is also used in the subsequent patterning process, making the fabrication procedures combined and simplified.

Moreover, the photosensitive insulating layer allows the use of a single material, instead of two different materials, to achieve the two purposes of fixing the semiconductor element and for use in the subsequent patterning process, thereby reducing the material cost.

In another preferred embodiment of the present invention, the method for fabricating a carrier integrated with a semiconductor elements comprises the steps of: providing a carrier having at least one opening therein, the carrier having an upper surface and a lower surface; attaching a supporting substrate to the lower surface of the carrier; embedding at least one semiconductor element in the opening of the carrier; forming a first photosensitive insulating layer over the upper surface of the carrier, and filling the first photosensitive insulating layer into a gap between the opening of the carrier and the semiconductor element, such that the semiconductor element is fixed in the opening; performing a patterning process on the first photosensitive insulating layer to form a plurality of recessed grooves in the first photosensitive insulating layer, such that input/output (I/O) electrode pads of the semiconductor element and predetermined portions of the carrier are exposed via the recessed grooves; applying a seed layer over the photosensitive insulating layer and in the recessed grooves, wherein the seed layer is connected to the I/O electrode pads of the semiconductor element; forming a second photosensitive insulating layer on the seed layer; patterning the second photosensitive insulating layer, such that the recessed grooves having the seed layer therein are exposed from the patterned second photosensitive insulating layer; forming a build-up circuit respectively in the recessed grooves; removing the second photosensitive insulating layer and the seed layer covered by second photosensitive insulating layer; and finally removing the supporting substrate.

The semiconductor element is fixed in the opening of the carrier by the means of the first photosensitive insulating layer. The first photosensitive insulating layer is patterned to form the recessed grooves such as contact holes and circuit slots. Then, the build-up circuit such as a conductive bump and a circuit layer is formed in the recessed grooves respectively. Therefore, the procedure of fixing the semiconductor element in the carrier and the procedure of fabricating the build-up circuit are combined in the same set of fabrication processes for the carrier structure, thereby effectively simplifying the overall fabrication processes and reducing the fabrication cost.

### BRIEF DESCRIPTION OF THE DRAWINGS

The present invention can be more fully understood by reading the following detailed description of the preferred embodiments, with reference made to the accompanying drawings, wherein:

FIGS. 1A to 1E are cross-sectional schematic diagrams showing procedural steps of a method for fabricating a carrier structure integrated with a semiconductor element according to a first preferred embodiment of the present invention; and

FIGS. 2A to 2F are cross-sectional schematic diagrams showing procedural steps of a method for fabricating a carrier structure integrated with a semiconductor element according to a second preferred embodiment of the present invention.

### DETAILED DESCRIPTION OF THE PREFERRED EMBODIMENTS

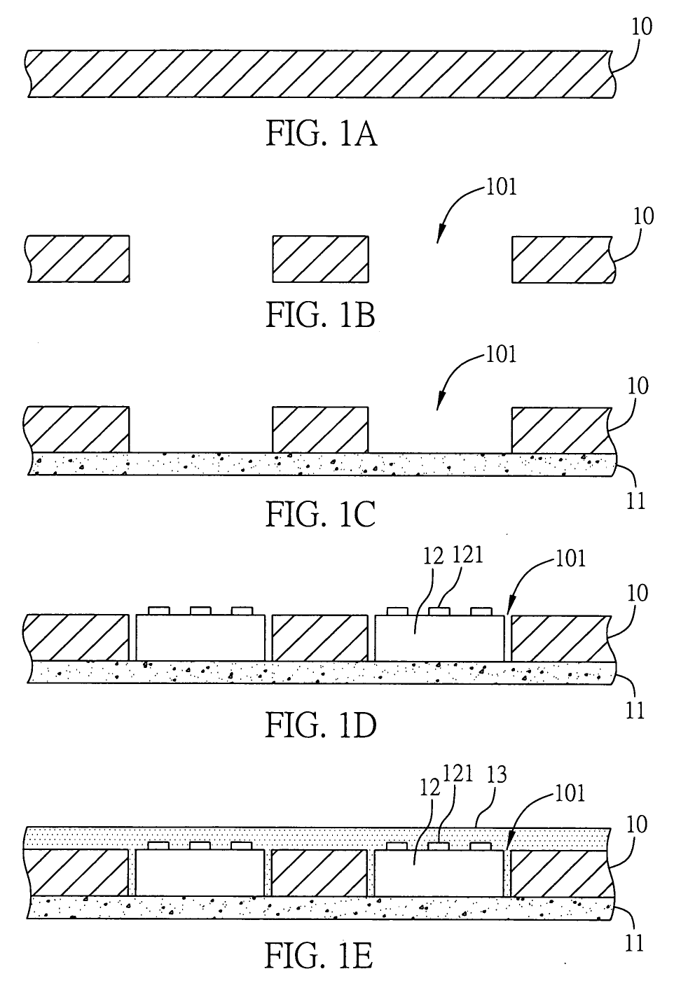

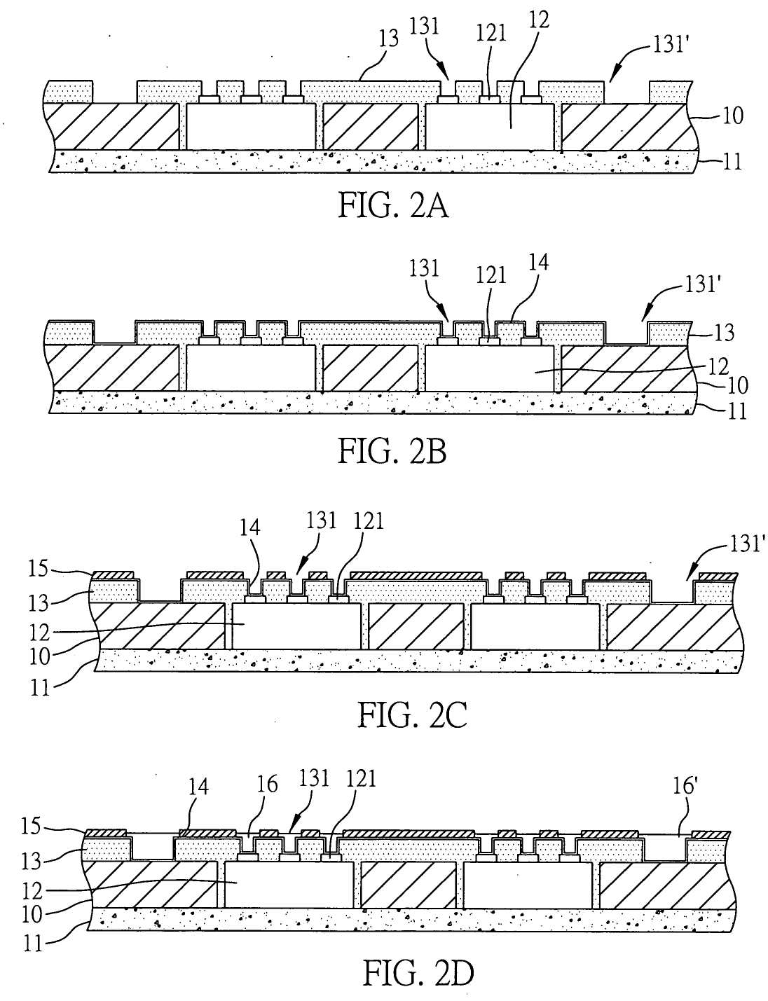

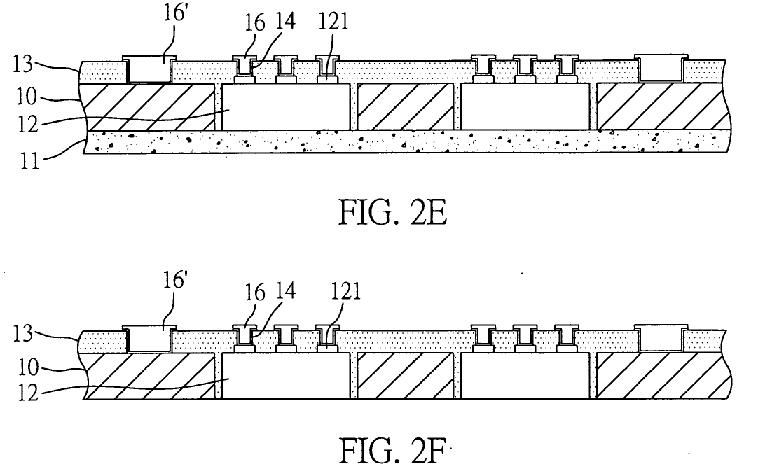

Preferred embodiments of a carrier structure integrated with a semiconductor element and a method for fabricating the same proposed in the present invention are described in detail as follows with reference to FIGS. 1A to 1E and FIGS. 2A to 2F.

### First Preferred Embodiment

FIGS. 1A to 1E are cross-sectional schematic diagrams showing procedural steps of the method for fabricating a carrier structure integrated with a semiconductor element according to a first preferred embodiment of the present invention.

Referring first to FIG. 1A, a carrier 10 is provided, which can be an insulating board, printed circuit board, laminated substrate, or build-up substrate, etc.

Referring to FIG. 1B, the carrier 10 is formed with at least one opening 101 therein.

Referring to FIG. 1C, then a supporting substrate 11 is attached to a lower surface of the carrier 10 to temporarily seal the bottom of the opening 101. The supporting substrate 11 can be a film, dry film, tape, metal board, or insulating board, etc.

Referring to FIG. 1D, at least one semiconductor element 12 is embedded in the opening 101 of the carrier 10. The semiconductor element 12 can be a chip or a chip-type passive component with a plurality of electrode pads 121 formed thereon, etc.

Referring to FIG. 1E, a photosensitive insulating layer 13 is formed by coating or pressing over an upper surface of the carrier 10 and the semiconductor element 12, and the photosensitive insulating layer 13 before being cured is filled into a gap between the opening 101 and the semiconductor element 12. After the photosensitive insulating layer 13 is cured, the semiconductor element 12 can be fixed in the opening 101.

By the foregoing method, a carrier structure integrated with a semiconductor element is fabricated. As shown in FIG. 1E, this carrier structure comprises a carrier 10 having at least one opening 101, at least one semiconductor element 12 embedded in the opening 101 of the carrier 10, and a photosensitive insulating layer 13 filled into a gap between the opening 101 and the semiconductor element 12, such that the photosensitive insulating layer 13 is used as a binding material to fix the semiconductor element 12 in the opening 101.

Moreover, besides fixing the semiconductor element 12 in place, the photosensitive insulating layer 13 is further used in a subsequent patterning process for fabrication of build-up circuits. Thus, provision of the photosensitive insulating layer 13 having the double uses eliminates the need of an additional binding material for fixing the semiconductor element 12, thereby saving the cost on the binding material. The photosensitive insulating layer 13 also allows the use of a single material, instead of two different materials, to achieve the two purposes of fixing the semiconductor element 12 and for use in the subsequent patterning process, thereby reducing the material and fabrication cost.

Furthermore, the photosensitive insulating layer 13 is applied over the surface of the carrier 10 and filled into the gap between the opening 101 and the semiconductor element 12, so as to fix the semiconductor element 12 in place and for use in the subsequent patterning process, which two procedures are thus combined. This simplifies the overall fabrication processes, improves a production speed, and decreases the fabrication cost.

### Second Preferred Embodiment

FIGS. 2A to 2F are cross-sectional schematic diagrams showing procedural steps of the method for fabricating a carrier structure integrated with a semiconductor element according to a second preferred embodiment of the present invention. In this second embodiment, the foregoing steps of FIGS. 1A to 1E are repeated and not to be further described here, which are followed by the steps shown in FIGS. 2A to 2F.

Referring to FIG. 2A, after the photosensitive insulating layer 13 is formed over the surface of the carrier 10 by coating or pressing (as shown in FIG. 1E), a patterning process is performed on the photosensitive insulating layer 13, such that recessed grooves 131, 131′ are formed in the photosensitive insulating layer 13, and electrode pads 121 of the semiconductor element 12 and predetermined portions on the surface of the carrier 10 are exposed via the recessed grooves 131, 131′ respectively. The recessed grooves 131, 131′ can be contact holes or circuit slots. The patterning process for forming the recessed grooves 131, 131′ includes exposing and developing procedures.

Referring to FIG. 2B, a seed layer 14 is applied over the photosensitive insulating layer 13 and in the recessed grooves 131, 131′, making the seed layer 14 connected to the electrode pads 121 of the semiconductor element 12. The seed layer 14 can be made of a titanium-wolfram/copper (TiW/Cu) alloy, a titanium-wolfram/aluminum (TiW/Al) alloy, a titanium/nickel-vanadium/copper (Ti/NiV/Cu) alloy, or a conductive polymer material.

Referring to FIG. 2C, another photosensitive insulating layer 15 is formed on the seed layer 14 and subjected to the foregoing patterning process, so as to allow the recessed grooves 131, 131′ having the seed layer 14 therein to be exposed from the patterned photosensitive insulating layer 15.

Referring to FIG. 2D, build-up circuits are respectively formed in the recessed grooves 131, 131′ via the seed layer 14 by an electroplating process. The build-up circuits comprise a circuit layer 16′ and conductive bumps 16, which are primarily made of copper.

Referring to FIG. 2E, the photosensitive insulating layer 15 and the seed layer 14 covered by the photosensitive insulating layer 15 are removed. Finally, referring to FIG. 2F, the supporting substrate 11 is removed, such that the build-up circuits are completely fabricated on the semiconductor element 12. Further, the fabrication processes of the build-up circuits can be repeated in the present invention to form a plurality of electroplated circuit layers on the semiconductor element. After applying a solder mask layer, the fabricated carrier structure may be subjected to a singulation process (not shown) and ready for later use.

By the foregoing method, a carrier structure integrated with a semiconductor element is fabricated. As shown in FIG. 2F, this carrier structure comprises a carrier 10 having at least one opening 101; at least one semiconductor element 12 embedded in the opening 101 of the carrier 10; a photosensitive insulating layer 13 formed over the carrier 10 and the semiconductor element 12 and filled into a gap between the opening 101 and the semiconductor element 12, wherein the photosensitive insulating layer 13 is patterned to form a plurality of recessed grooves 131, 131′ therein, and electrode pads 121 of the semiconductor element 12 and predetermined portions of the carrier 10 are exposed via the recessed grooves 131, 131′; a seed layer 14 applied in the recessed grooves 131, 131′; and build-up circuits comprising conductive bumps 16 and circuit layers 16′ are formed in the recessed grooves 131, 131′ via the seed layer 14 by electroplating.

In the foregoing fabrication method according to the present invention, the build-up circuits are formed on the electrode pads 121 of the semiconductor element 12 and the carrier 10 after embedding the semiconductor element 12 in the opening 101 of the carrier 10. The recessed grooves 131, 131′ required for fabricating the build-up circuits are formed in the photosensitive insulating layers 13, 15, such that the photosensitive insulating layer 13 for fixing the semiconductor element 12 in the carrier 10 can also be used in a subsequent procedure for fabricating the build-up circuits on the electrode pads 121 of the semiconductor element 12 and the carrier 10. This combines the procedure of fixing the semiconductor element 12 in the carrier 10 and the procedure of fabricating the build-up circuits in the same set of fabrication processes for the carrier structure, thereby effectively simplifying the overall fabrication processes and reducing the fabrication cost.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a carrier structure integrated with a semiconductor element, comprising the steps of:
providing a carrier having at least one opening therein, the carrier having an upper surface and a lower surface;
embedding at least one semiconductor element in the opening of the carrier; and
forming a photosensitive insulating layer over the upper surface of the carrier, and filling the photosensitive insulating layer into a gap between the opening of the carrier and the semiconductor element, such that the semiconductor element is fixed in the opening.

2. The method of claim 1, wherein the carrier is one selected from the group consisting of an insulating board, printed circuit board, laminated substrate, and build-up substrate.

3. The method of claim 1, further comprising a step of attaching a supporting substrate to the lower surface of the carrier.

4. The method of claim 3, wherein the supporting substrate is one selected from the group consisting of a film, dry film, tape, metal board, and insulating board.

5. The method of claim 1, wherein the semiconductor element is a chip or a chip-type passive component.

6. A method for fabricating a carrier structure integrated with a semiconductor element, comprising the steps of:
providing a carrier having at least one opening therein, the carrier having an upper surface and a lower surface;
embedding at least one semiconductor element in the opening of the carrier;
forming a first photosensitive insulating layer over the upper surface of the carrier, and filling the first photosensitive insulating layer into a gap between the opening of the carrier and the semiconductor element, such that the semiconductor element is fixed in the opening;
performing a patterning process on the first photosensitive insulating layer to form a plurality of recessed grooves in the first photosensitive insulating layer, such that electrode pads of the semiconductor element and predetermined portions of the carrier are exposed via the recessed grooves;
forming a seed layer over the first photosensitive insulating layer and in the recessed grooves, wherein the seed layer is connected to the electrode pads of the semiconductor element;
forming a second photosensitive insulating layer on the seed layer;
patterning the second photosensitive insulating layer, so as to allow the recessed grooves having the seed layer therein to be exposed from the patterned second photosensitive insulating layer;
forming a build-up circuit respectively in the recessed grooves via the seed layer by an electroplating process; and
removing the second photosensitive insulating layer and the seed layer covered by the second photosensitive insulating layer.

7. The method of claim 6, wherein the carrier is one selected from the group consisting of an insulating board, printed circuit board, laminated substrate, and build-up substrate.

8. The method of claim 6, further comprising a step of attaching a supporting substrate to the lower surface of the carrier.

9. The method of claim 8, wherein the supporting substrate is one selected from the group consisting of a film, dry film, tape, metal board, and insulating board.

10. The method of claim 6, wherein the semiconductor element is a chip or a chip-type passive component.

11. The method of claim 6, wherein the seed layer is made of a material selected from the group consisting of a titanium-wolfram/copper (TiW/Cu) alloy, a titanium-wolfram/aluminum (TiW/Al) alloy, a titanium/nickel-vanadium/copper (Ti/NiV/Cu) alloy, and a conductive polymer.

12. The method of claim 6, wherein the build-up circuit comprises a conductive bump.

13. The method of claim 6, wherein the build-up circuit comprises a circuit layer.

14. The method of claim 8, further comprising a step of removing the supporting substrate after removing the second photosensitive insulating layer and the seed layer covered thereby.
